(19) United States
(12) Patent Application Publication
(10) Pub. No.: US 2021/0407554 A1
(43) Pub. Date: Dec. 30, 2021

(54) SEMICONDUCTOR DEVICE

(71) Applicant: CHANGXIN MEMORY TECHNOLOGIES, INC., Hefei City (CN)

(72) Inventor: Shuliang NING, Hefei City (CN)

(73) Assignee: CHANGXIN MEMORY TECHNOLOGIES, INC., Hefei City (CN)

(21) Appl. No.: 17/376,090

(22) Filed: Jul. 14, 2021

Related U.S. Application Data
(63) Continuation of application No. PCT/CN2020/128132, filed on Nov. 11, 2020.

(30) Foreign Application Priority Data
Jun. 30, 2020 (CN) 202010611284.3

(51) Int. Cl. G11C 7/04; G01K 7/01; G11C 11/4074

(52) U.S. Cl. CPC G11C 7/04; G11C 11/4074; G01K 7/01

(57) ABSTRACT

A semiconductor device includes a storage chip and a temperature sensor for detecting the temperature of the storage chip, the temperature sensor and the storage chip being powered by different power supplies. The storage chip and the temperature sensor can use different power supplies. As such, the activations of both of them can be controlled separately, i.e., the activation of the temperature sensor is free from whether a storage chip is activated, so that the detection of the temperature of the storage chip is not affected by whether a storage chip is activated, thereby providing a reference for the activation and operation of the storage chip, and in turn avoiding the activation or operation of the storage chip under low temperatures and improving the stability of the storage chip.

### CROSS-REFERENCE TO RELATED APPLICATIONS

This application is a continuation of International Patent Application No. PCT/CN2020/128132 filed on Nov. 11, 2020, which claims priority to Chinese Patent Application No. 202010611284.3 filed on Jun. 30, 2020. The disclosures of these applications are hereby incorporated by reference in their entirety.

### BACKGROUND

Dynamic Random-Access Memory (DRAM) is a semiconductor storage device commonly used in computers, and its storage array region consists of many repeating storage cells. Each of the storage cells typically includes a capacitor and a transistor, wherein the gate of the transistor is connected to a word line, the drain is connected to a bit line, and the source electrode is connected to the capacitor. The voltage signal over the word line can control ON/OFF of the transistor, and then data information stored in the capacitor is read through the bit line, or data information is written through the bit line to the capacitor for storage.

### SUMMARY

Various embodiments of the present disclosure provide a semiconductor device that enables the activation of a temperature detection unit or temperature sensor to be free from whether a storage chip is activated such that the detection of the temperature of the storage chip is not affected by whether a storage chip is activated.

Some embodiments the present disclosure provide a semiconductor device that includes a storage chip and a temperature detection unit for detecting the temperature of the storage chip, wherein the temperature detection unit and the storage chip are powered by different power supplies.

In some embodiments, the power supplied to the temperature detection unit is earlier than the power supplied to the storage chip.

In some embodiments, the temperature detection unit is disposed in the storage chip.

In some embodiments, the temperature detection unit and the storage chip share the same grounding terminal.

In some embodiments, one or more storage chips are provided, and in the case of a plurality of the storage chips, the plurality of the storage chips are sequentially stacked upwardly.

In some embodiments, in the case of a plurality of the storage chips, the storage chips are electrically connected to the grounding terminal and the power supply with a through-silicon-via interconnecting structure.

In some embodiments, the temperature detection unit is electrically connected to the power supply with an interconnecting structure of through silicon vias.

In some embodiments, one or more temperature detection units is provided.

In some embodiments, the temperature detection unit is one-to-one corresponding to the storage chip.

In some embodiments, the semiconductor device further includes a control chip, wherein the storage chip and the temperature detection unit are electrically connected to the control chip.

In some embodiments, the storage chip is disposed on the control chip.

In some embodiments, the semiconductor device further includes a wiring substrate having connection lines provided therein, wherein both of the storage chip and the control chip are located on the wiring substrate, and the storage chip and the control chip are electrically connected through the connection lines in the wiring substrate.

In some embodiments, the control chip is configured to heat the storage chip prior to the activation of the storage chip, and to judge whether a temperature detected by the temperature detection unit reaches a set threshold, and to control the activation of the storage chip if the set threshold is reached.

In some embodiments, the control chip supplies power to the storage chip so as to control the activation of the storage chip.

In some embodiments, the control chip is first activated before heating the storage chip, and the control chip heats the storage chip by heat generated itself after activation.

In some embodiments, the control chip controls the activation of the temperature detection unit after being activated.

In some embodiments, the control chip has an additional heating circuit provided therein for heating the storage chip.

In some embodiments, before or after the control chip heats the storage chip, the control chip judges whether a temperature of the storage chip detected by the temperature detection unit reaches a set threshold. If the set threshold is not reached, then the control chip controls the heating circuit to heat the storage chip; and if the set threshold is reached, then the control chip controls the heating circuit to stop heating the storage chip.

In some embodiments, the storage chip is a DRAM chip.

Various embodiments of the present disclosure can have one or more of the following advantages.

The storage chip and the temperature detection unit use different power supplies. As such, the activations of both of them can be controlled separately, i.e., the activation of the temperature detection unit is free from, or independent of, whether a storage chip is activated, so that the detection of the temperature of the storage chip is free from whether a storage chip is activated, thereby providing a reference for the activation and operation of the storage chip, and in turn avoiding the activation or operation of the storage chip under low temperatures and improving the stability of the storage chip.

### BRIEF DESCRIPTION OF THE DRAWINGS

FIG. 1 is a schematic structural diagram of a first embodiment of a semiconductor device according to some embodiments the present disclosure;

FIG. 2 is a schematic circuit diagram of the first embodiment of the semiconductor device according to some embodiments the present disclosure;

FIG. 3 is a timing diagram of supplying power to the temperature detection unit 110 and the storage chip 100;

FIG. 4 is a schematic structural diagram of a second embodiment of the semiconductor device according to some embodiments the present disclosure;

FIG. 5 is a schematic structural diagram of a third embodiment of the semiconductor device according to some embodiments the present disclosure; and

FIG. 6 is a schematic structural diagram of a fourth embodiment of the semiconductor device according to some embodiments the present disclosure.

### DETAILED DESCRIPTION

Semiconductor devices according to some embodiments the present disclosure are detailed below in combination with drawings.

Temperature can have a great effect on memory write. In low-temperature environments, in the case of writing to memory, problems such as long writing time and low writing stability can arise.

When a memory device operates in low temperature environments, the stability of memory write can be affected because a temperature drop may cause increased resistances of the word line, bit line, metal connecting line (metal contacting portion), or the like in the memory, and the increased resistances may cause varied or extended time when data is written into memory.

Therefore, various embodiments of the present disclosure provide a semiconductor device with a temperature detection unit to detect the temperature of the storage chip so as to provide a reference for the activation and operation of the storage chip, thereby avoiding the activation and operation of the storage chip under low temperatures, shortening write time, and improving the stability of the storage chip write.

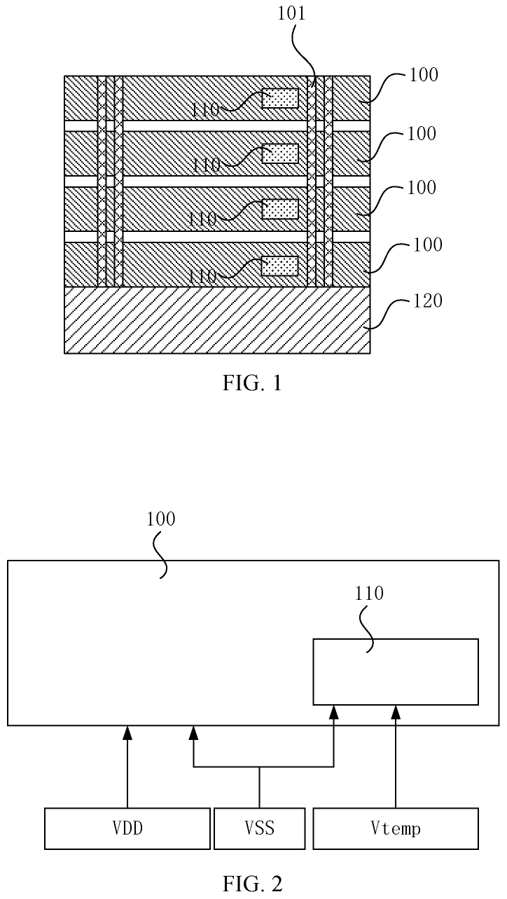

FIG. 1 is a schematic structural diagram of the first embodiment of the semiconductor device. Referring to FIG. 1, the semiconductor device according to some embodiments the present disclosure includes a storage chip 100 and a temperature detection unit 110.

The storage chip 100 is an existing memory capable of performing data write, data read, and/or data deletion. The storage chip 100 is formed by the semiconductor integration fabricating process. Specifically, the storage chip 100 can include a storage array and peripheral circuits connected to the storage array. The storage array includes a plurality of storage cells and bit lines, word lines, and metal connecting lines (metal contacting portions) that are connected to the storage cells. The storage cells are configured to store data, and the peripheral circuits are related circuits when operations are performed on the storage arrays. In the present embodiment, the storage chip 100 is a DRAM storage chip, which includes a plurality of storage cells. The storage cell includes a capacitor and a transistor. The gate of the transistor is connected to a word line, the drain is connected to a bit line, and the source electrode is connected to the capacitor. In other embodiments, as the storage chip 100, other types of storage chips may be used.

The temperature detection unit 110 is configured to detect the temperature of the storage chip 100. The temperature detection unit 110 includes a temperature sensor for sensing a temperature and converting the sensed temperature to an electric signal. The temperature sensor may be a PN junction diode temperature sensor or a capacitive temperature sensor.

The semiconductor device includes one or more storage chips 100 and one or more temperature detection units 110. The temperature detection unit 110 may be configured to detect the temperature(s) of one or more storage chips 100. The temperature detection unit 110 may be in one-to-one relationship or one-to-many relationship with the storage chip 100.

When the number of the storage chip 100 is one, and the number of the temperature detection unit 110 is also one, the temperature detection unit 110 is in one-to-one relationship with the storage chip 100 and configured to merely detect the temperature of this storage chip 100.

When the number of the storage chip 100 is more than one, and the number of the temperature detection unit 110 is one, the temperature detection unit 110 is in one-to-many relationship with the storage chip 100 and configured to detect the temperatures of the more than one storage chips 100.

When the number of the storage chip 100 is more than one, and the number of the temperature detection unit 110 is also more than one, but the number of the temperature detection unit 110 is less than the number of the storage chip 100, the temperature detection unit 110 and the storage chip 100 may have one-to-one relationship and one-to-many relationship simultaneously, or have one-to-many relationship only. That is, there may be the situation where one of the temperature detection units 110 detects one storage chip 100 only and one temperature detection unit 110 detects more than one of the storage chips 100, or only the situation where one temperature detection unit 110 detects more than one of the storage chips 100.

When the number of the storage chip 100 is more than one, the number of the temperature detection unit 110 is also more than one, and the number of the temperature detection unit 110 equals to the number of the storage chip 100, the temperature detection unit 110 is in one-to-one relationship with the storage chip 100, and one temperature detection unit 110 is configured to detect the temperature of one of the storage chips 100.

In the present embodiment, the semiconductor device includes a plurality of storage chips 100 disposed as a stack and a plurality of temperature detection unit 110 one-to-one corresponding to the storage chips 100. Four storage chips 100 and four temperature detection units 110 are schematically depicted in FIG. 1.

The temperature detection units 110 and the storage chips 100 are powered by different power supplies. FIG. 2 is a schematic diagram of the circuit connections of the first embodiment of the semiconductor device n. Referring to FIG. 2, the temperature detection unit 110 is powered by a power supply Vtemp, and the storage chip 100 is powered by VDD. Since the temperature detection unit 110 and the storage chip 100 are powered by different power supplies, the power supplied to the temperature detection unit 110 and the power supplied to the storage chip 100 can be controlled independently, thereby enabling the temperature detection unit 110 to be activated at a different time from the storage chip 100.

As described above, temperature has a great influence on the performance of the storage chip 100, especially when the storage chip 100 is activated. If the storage chip 100 is activated under low temperatures, the time of writing data into the storage chip 100 may vary or extend, affecting the stability of the storage chip 100. Therefore, the temperature of the storage chip is required to be measured before the activation of the storage chip 100 such that the storage chip 100 can be activated within a suitable temperature.

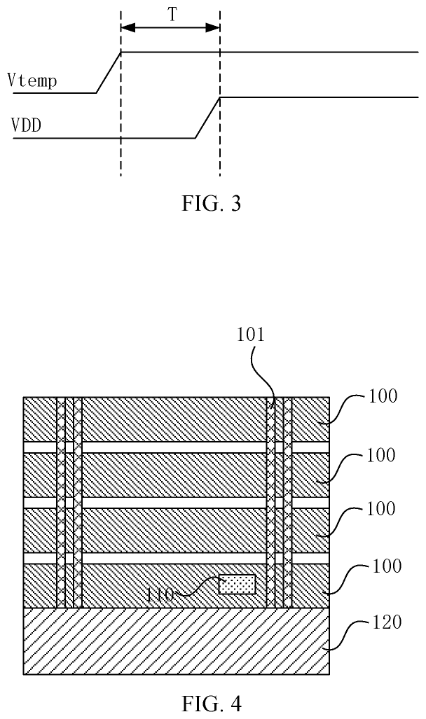

Therefore, in some embodiments of the present disclosure, the power supplied to the temperature detection unit 110 is earlier than the power supplied to the storage chip 100, i.e., before the storage chip 100 is activated, the temperature detection unit 110 has been activated, and thus, the temperature prior to the activation of the storage chip 100 can be acquired so as to provide a reference for the activation of the storage chip 100. FIG. 3 is a timing diagram of supplying power to the temperature detection unit 110 and the storage chip 100. Referring to FIG. 3, after power is supplied to the temperature detection unit 110 for time T, power is supplied to the storage chip 100. The time may be a preset time, or the time taken by the temperature of the storage chip 100 to reach a set threshold temperature.

In some embodiments, referring to FIG. 2, the temperature detection unit 110 and the storage chip 100 share the same grounding terminal VSS. The advantage thereof is as follows. On one hand, the leakage current of the non-activated phase of the storage chip 100 will not increase, and on the other hand, the number of the pins will reduce, thereby saving space.

In the present embodiment, the semiconductor device further includes a control chip 120. The storage chip 100 and the temperature detection unit 110 are electrically connected to the control chip 120. The control chip 120 is configured to control the activation and operation of the storage chip 100 and the temperature detection unit 110. The grounding terminal VSS, the power supply VDD and the power supply Vtemp are provided by the control chip 120. The activation of the storage chip 100 includes power up and self-check, and the operation of the storage chip 100 includes writing data to the storage chip 100, reading data from the storage chip 100, and deleting the accessed data in the storage chip 100, or the like. A plurality of storage chips 100 are stacked on the control chip 120, which bonds with the storage chip 100 at the bottommost layer of the stack structure. However, in another embodiment of the present disclosure, when only one storage chip 100 is provided, this storage chip 100 is disposed on and bonds with the control chip 120.

The storage chip 100 has a through-silicon-via interconnecting structure 101 formed therein. With the through-silicon-via interconnecting structure 101, the storage chip 100 is electrically connected to the control chip 120, and the temperature detection unit 110 is electrically connected to the control chip 120. That is, with the through-silicon-via interconnecting structure 101, the storage chip 100 is electrically connected to the grounding terminal VSS and the power supply VDD, and the temperature detection unit 110 is electrically connected to the power supply Vtemp and the grounding terminal VSS. Specifically, in the present embodiment, when the plurality of the storage chips 100 are stacked, each of the storage chips 100 may be connected to the control chip 120 through different through-silicon-via interconnecting structures; when a plurality of the temperature detection units 110 is provided, there may be the situation where each of the temperature detection units 110 is connected to the control chip 120 through through-silicon-via interconnecting structures, and also the situation where the plurality of the temperature detection units 110 share the through-silicon-via interconnecting structure so as to connect to the control chip 120. It can be understood that the storage chip 100 and the temperature detection units 110 are connected to the control chip 120 through different through-silicon-via interconnecting structures such that the temperature detection units 110 and the storage chip 100 can be powered by different power supplies. In some embodiments, the power supplying of the plurality of the temperature detection units 110 may also share the technology of through-silicon-via interconnecting structure.

In other embodiments, the storage chip 100 and the temperature detection unit may also electrically connect to the control chip 120 by metal leads (formed by the lead bonding process).

In some embodiments, the temperature detection unit 110 may be formed in the storage chip 100 by the semiconductor integration fabricating process. In the case of merely detecting the temperature of one storage chip 100, the temperature detection unit 110 may be formed in this storage chip 100. For example, in the present embodiment, as shown in FIG. 1, the temperature detection units 110 are one-to-one corresponding to the storage chips 100, and each storage chip 100 is provided with one temperature detection unit 110 therein. In the case of detecting the temperatures of a plurality of the storage chips 100, the temperature detection unit 110 may be formed in any one of the plurality of the storage chips 100 or in the storage chip 100 at the centered or bottommost layer. For example, in the second embodiment of the present disclosure, referring to FIG. 4 which is a schematic structural diagram of the second embodiment of the semiconductor device, the temperature detection unit 110 is disposed in the storage chip 100 at the bottommost layer and capable of measuring the temperatures of four storage chips 100.

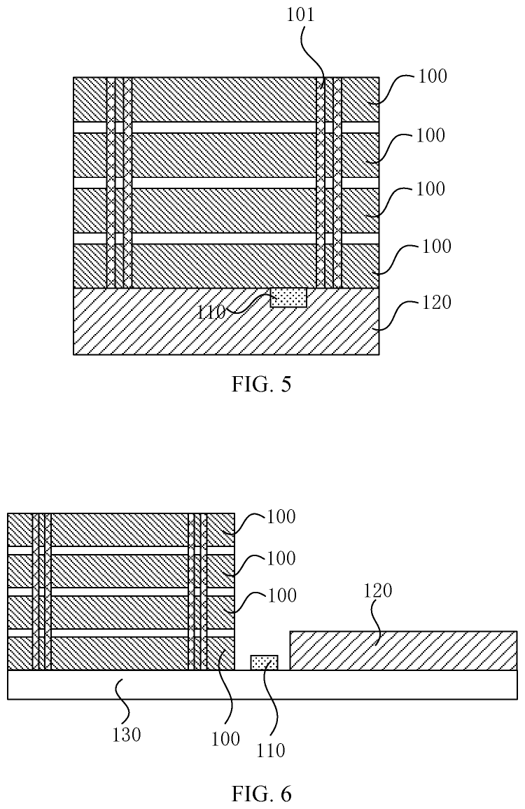

In another embodiment of the present disclosure, the temperature detection unit 110 is disposed in the control chip 120 rather than a storage chip 100. Specifically, referring to FIG. 5 which is a schematic structural diagram of the third embodiment of the semiconductor device, the temperature detection unit 110 is disposed in the control chip 120 and capable of measuring the temperatures of four storage chips 100 stacked on the control chip 120.

In another embodiment of the present disclosure, referring to FIG. 6 which is a schematic structural diagram of the fourth embodiment of the semiconductor device, the semiconductor device further includes a wiring substrate 130 having connection lines (not depicted in the drawing) provided therein, wherein both of the storage chip 100 and the control chip 120 are located on the wiring substrate 130, and the storage chip 100 and the control chip 120 are electrically connected through the connection lines in the wiring substrate 130. In this embodiment, the temperature detection unit 110 is also disposed on the wiring substrate 130 and configured to measure the ambient temperature. This ambient temperature is close to the temperature of the storage chip 100 and may be approximately as the temperature of the storage chip 100. The wiring substrate 130 includes, but not limited to, a PCB circuit board. It can be understood that, in other embodiments of the present disclosure, the temperature detection unit 110 may not be disposed on the wiring substrate 130, and is disposed in the storage chip 100 or the control chip 120, as shown in FIGS. 1, 4 and 5.

In the semiconductor device according to some embodiments the present disclosure, the storage chip and the temperature detection unit use different power supplies, and thus, the activations of both of them can be controlled separately, i.e., the activation of the temperature detection unit is free from whether a storage chip is activated, so that the detection of the temperature of the storage chip is free from whether a storage chip is activated, thereby providing a reference for the activation and operation of the storage chip, and in turn avoiding the activation or operation of the storage chip under low temperatures and improving the stability of the storage chip.

When the storage chip 100 is in a low temperature environment, if the storage chip 100 is heated, then the temperature thereof increases quickly, thereby expediting the activation of the storage chip 100. Therefore, the control chip 120 according to some embodiments the present disclosure can further be activated prior to the activation of the storage chip 100, and the control chip 120 heats the storage chip 100 by heat generated itself after activation so as to raise the temperature of the storage chip 100 quickly.

After being activated, the control chip 120 controls the activation of the temperature detection unit 110 so as to detect the temperature of the storage chip 100. The temperature detection unit 110 can further transmit the detected temperature to the control chip 120 as the data of the control chip 120.

The control chip 120 can judge whether a temperature detected by the temperature detection unit 110 reaches a set threshold, and control the activation of the storage chip 100 if the set threshold is reached. The control chip can control the activation of the storage chip by supplying power to the storage chip.

If only one temperature detection unit 110 and one storage chip 100 are provided, and the one temperature detection unit 110 is configured to merely detect the temperature of one storage chip 100, when the control chip 120 judges that the temperature detected by this temperature detection unit 110 reaches a set threshold, then the control chip 120 controls the activation of this storage chip 100.

If one temperature detection unit 110 and a plurality of storage chips 100 are provided, and the one temperature detection unit 110 is configured to detect the temperatures of the plurality of storage chips 100, when the control chip 120 judges that the temperature detected by this temperature detection unit 110 reaches a set threshold, then the control chip 120 first controls the activation of the storage chip 100 closest to the control chip 120, and then controls the subsequent activations of other storage chips 100 above.

If a plurality of temperature detection units 110 and a plurality of storage chips 100 are provided, there may be the situation where one of the temperature detection units 110 merely detects one storage chip 100 and one temperature detection unit 110 detects a plurality of the storage chips 100, or only the situation where one temperature detection unit 110 detects a plurality of the storage chips 100. When the control chip 120 judges that the temperature detected by a certain temperature detection unit 110 reaches a set threshold, the control chip 120 controls the activation of the storage chip 100 corresponding to this temperature detection unit 110, and if this temperature detection unit 110 detects the temperatures of a plurality of the storage chips 100, then the control chip 120 first controls the activation of the storage chip 100 closest to the control chip 120, and then controls the subsequent activations of other storage chips 100 above.

If a plurality of temperature detection units 110 and a plurality of storage chips 100 are provided, and the plurality of temperature detection units 110 are one-to-one corresponding to the plurality of storage chips 100, when the control chip 120 judges that the temperature detected by a certain temperature detection unit 110 reaches a set threshold, the control chip 120 controls the activation of the storage chip 100 corresponding to this temperature detection unit 110. Specifically, there are four storage chips 100 in the stack structure as shown in FIG. 1, each of the storage chips 100 has one temperature detection unit 110 correspondingly, and thus, each of the temperature detection units 110 detects the temperature of the corresponding storage chip 100, obtaining four detection values of temperature. The control chip 120 sequentially judges whether the temperatures detected by the four of the temperature detection units 110 reach a set threshold, and if a temperature detected by a certain temperature detection unit 110 reaches the set threshold, then the control chip 120 controls the activation of the storage chip corresponding to this temperature detection unit 110. For example, if the temperature detected by the temperature detection unit 110 in the storage chip 100 at the bottommost layer of the stack structure first reaches the set threshold, then the control chip 120 first controls the activation of the storage chip 100 at the bottommost layer of the stack structure; next, if the temperature detected by the corresponding temperature detection unit 110 in the storage chip 100 at the last but one layer of the stack structure also reaches the set threshold, the control chip 120 then controls the activation of the storage chip 100 at the last but one layer of the stack structure; the activation of the storage chips 100 at the two layers above are performed similarly.

For the semiconductor device having a plurality of storage chips 100, such aforementioned control structure and control manner further improve the precision of the activation timing of each storage chip 100, further shorten the write time when data is written to each storage chip 100 in a low temperature environment, and further improves the stability of writing to each storage chip 100.

When the semiconductor device according to some embodiments the present disclosure operates in a low temperature environment, the temperature of the storage chip 100 can be raised to the set threshold by the control chip 120, preventing the increased resistances of the word line, bit line and metal connecting line (metal contacting portion) in the storage chip 100 due to the excessive low ambient temperature, thereby shortening the write time when data is written into the storage chip in a low temperature environment and improving the stability of writing to the storage chip. The set threshold may be set in the control chip 120, and the specific magnitude of the set threshold may be set as needed or based on experience.

In another embodiment, the control chip 120 may have an additional heating circuit (not depicted in the drawing) provided therein. The heating circuit is configured to heat the storage chip 100. Before or after the control chip 120 heats the storage chip 100, the control chip 120 judges whether a temperature of the storage chip 100 detected by the temperature detection unit 110 reaches a set threshold. If the set threshold is not reached, then the control chip controls the heating circuit to heat the storage chip 100; and if the set threshold is reached, then the control chip controls the heating circuit to stop heating the storage chip 100. Therefore, the accurate control of the heating process is realized such that the temperature of the storage chip 100 can be kept around the set threshold, preventing the excessive high or excessive low temperature of the storage chip 100, and thus, the write time to memory is always short.

The description above is merely the preferred implementations of the present disclosure. It should be noted that the ordinary skills in the art could further make several improvements and embellishments without departing the principle of the present disclosure, and these improvements and embellishments should also be considered as the scope sought for protection in the present disclosure.

What is claimed is:

1. A semiconductor device, comprising:
a storage chip; and
a temperature sensor configured to detect a temperature of the storage chip,
wherein the temperature sensor and the storage chip are powered by different power supplies.

2. The semiconductor device according to claim 1, wherein the power supplied to the temperature sensor is earlier than the power supplied to the storage chip.

3. The semiconductor device according to claim 2, wherein the temperature sensor is disposed in the storage chip.

4. The semiconductor device according to claim 3, wherein the temperature sensor and the storage chip share the same grounding terminal.

5. The semiconductor device according to claim 3, wherein one or more storage chips are provided, and in the case of a plurality of the storage chips, the plurality of the storage chips are sequentially stacked upwardly.

6. The semiconductor device according to claim 5, wherein in the case of a plurality of the storage chips, the storage chips are electrically connected to the grounding terminal and the power supply with a through-silicon-via interconnecting structure.

7. The semiconductor device according to claim 6, wherein the temperature sensor is electrically connected to the power supply with a through-silicon-via interconnecting structure.

8. The semiconductor device according to claim 5, wherein one or more temperature sensors are provided.

9. The semiconductor device according to claim 8, wherein the temperature sensor is one-to-one corresponding to the storage chip.

10. The semiconductor device according to claim 3, wherein the semiconductor device further comprises a control chip, the storage chip and the temperature sensor being electrically connected to the control chip.

11. The semiconductor device according to claim 10, wherein the storage chip is disposed on the control chip.

12. The semiconductor device according to claim 10, further comprising a wiring substrate having connection lines provided therein, both of the storage chip and the control chip locating on the wiring substrate, the storage chip and the control chip being electrically connected through the connection lines in the wiring substrate.

13. The semiconductor device according to claim 10, wherein the control chip is configured to heat the storage chip prior to the activation of the storage chip, and to judge whether a temperature detected by the temperature sensor reaches a set threshold, and to control the activation of the storage chip if the set threshold is reached.

14. The semiconductor device according to claim 13, wherein the control chip supplies power to the storage chip so as to control the activation of the storage chip.

15. The semiconductor device according to claim 13, wherein the control chip is first activated before heating the storage chip, and the control chip heats the storage chip by heat generated itself after activation.

16. The semiconductor device according to claim 15, wherein after being activated, the control chip controls the activation of the temperature sensor.

17. The semiconductor device according to claim 13, wherein the control chip has an additional heating circuit provided therein for heating the storage chip.

18. The semiconductor device according to claim 17, wherein before or after the control chip heats the storage chip, the control chip judges whether a temperature of the storage chip detected by the temperature sensor reaches a set threshold; if the set threshold is not reached, then the control chip controls the heating circuit to heat the storage chip; and if the set threshold is reached, then the control chip controls the heating circuit to stop heating the storage chip.

19. The semiconductor device according to claim 13, wherein the storage chip is a DRAM chip.

20. The semiconductor device according to claim 1, wherein activation of the temperature sensor is independent of whether the storage chip is activated, such that detection of the temperature of the storage chip is independent of whether the storage chip is activated, thereby providing a reference for the activation and operation of the storage chip, and avoiding the activation or the operation of the storage chip under low temperatures.
